(19) United States
(12) Patent Application Publication
(10) Pub. No.: US 2013/0288399 A1
(43) Pub. Date: Oct. 31, 2013

(54) ENERGY BEAM PROCESSING APPARATUS AND ENERGY BEAM PROCESSING METHOD

(71) Applicant: FUJITSU LIMITED, Kawasaki-shi (JP)

(72) Inventor: Hiroyuki FUJIMOTO, Kawasaki (JP)

(73) Assignee: FUJITSU LIMITED, Kawasaki-shi (JP)

(21) Appl. No.: 13/927,817

(22) Filed: Jun. 26, 2013

Related U.S. Application Data
(63) Continuation of application No. PCT/JP2010/073778, filed on Dec. 28, 2010.

(51) Int. Cl. H01L 21/768

(52) U.S. Cl. CPC H01L 21/76892
USPC 438/4; 204/298.32

(57) ABSTRACT

An energy beam processing apparatus cutting an interconnection by irradiating the interconnection with an energy beam while scanning, the energy beam processing apparatus including an irradiation unit which irradiates the interconnection with the energy beam while scanning; a measurement unit which measures a resistance value of the interconnection; and a control unit which controls a scan and an irradiation of the energy beam by the irradiation unit, the control unit controlling at least one of a scan rate and an irradiation intensity of the energy beam in accordance with a resistance value measured by the measurement unit, and controlling the irradiation unit to stop the irradiation of the energy beam when the resistance value measured by the measurement unit exceeds a prescribed value.

### CROSS-REFERENCE TO RELATED APPLICATION

This application is a Continuation of PCT application No. PCT/JP2010/073778, which was filed on Dec. 28, 2010, and which designated the United States of America, the entire contents of which are incorporated herein by reference.

### FIELD

The embodiments discussed herein are related to an energy beam processing apparatus and an energy beam processing method.

### BACKGROUND

When a semiconductor device has a defect, often a repair, etc. of a circuit of the semiconductor device is made.

When the repair, etc. of the circuit of the semiconductor device is made, a cut of an interconnection, etc. is suitably made.

The interconnection is cut by irradiating a focused ion beam to the interconnection with, e.g., an FIB (Focused Ion Beam) apparatus or others, which irradiates the focused ion beam.

The background arts are as follows.

Japanese Laid-open Patent Publication No. Sho 62-15833;

Japanese Laid-open Patent Publication No. 2005-166726; and

Japanese Laid-open Patent Publication No. 2000-150407.

### SUMMARY

According to an aspect of an embodiment, an energy beam processing apparatus cutting an interconnection by irradiating the interconnection with an energy beam while scanning, the energy beam processing apparatus including an irradiation unit which irradiates the interconnection with the energy beam while scanning; a measurement unit which measures a resistance value of the interconnection; and a control unit which controls a scan and an irradiation of the energy beam by the irradiation unit, the control unit controlling at least one of a scan rate and an irradiation intensity of the energy beam in accordance with a resistance value measured by the measurement unit, and controlling the irradiation unit to stop the irradiation of the energy beam when the resistance value measured by the measurement unit exceeds a prescribed value.

According to another aspect of the embodiment, an energy beam processing method cutting an interconnection by irradiating the interconnection with the energy beam while scanning, the energy beam processing method including irradiating the interconnection with the energy beam while scanning while controlling at least one of a scan rate and an irradiation intensity of the energy beam in accordance with a resistance value of the interconnection; and stopping the irradiation of the energy beam when the resistance value of the interconnection exceeds a prescribed value.

The object and advantages of the embodiments will be realized and attained by means of the elements and combinations particularly pointed out in the claims.

It is to be understood that both the foregoing general description and the following detailed description are exemplary and explanatory and are not restrictive of the embodiments, as claimed.

### BRIEF DESCRIPTION OF DRAWINGS

FIG. 1 is a diagrammatic view of an energy beam processing apparatus according to a first embodiment;

FIG. 2 is an enlarged perspective view of a part of the energy beam processing apparatus according to the first embodiment;

FIG. 3 is a flow chart of the energy beam processing method according to the first embodiment;

FIG. 4 is a plan view (Part 1) of an example of a region-to-be-irradiated and partial regions;

FIG. 5 is the plan view (Part 2) of an example of a region-to-be-irradiated and partial regions;

FIG. 6 is a table of threshold values, scan rates and standby periods of time of respective stages of the first embodiment;

FIGS. 7A to 8B are time charts of an irradiation of an ion beam in the first embodiment;

FIG. 9 is a graph illustrating a relationship between a resistance value of an interconnection and a scan rate;

FIG. 10 is a graph illustrating a relationship between the resistance value of the interconnection and the standby period of time;

FIG. 11 is a table of the threshold values, the scan rates and the standby periods of time of the respective stages of a first modification of the first embodiment;

FIG. 12 is a table of the threshold values, the scan rates and the standby periods of time of the respective stages of a second modification of the first embodiment;

FIG. 13 is a flow chart of an energy beam processing method according to a second embodiment;

FIG. 14 is a table illustrating the threshold values and the irradiation intensities of the respective stages of the second embodiment;

FIG. 15A to 16B are time charts illustrating an irradiation of an ion beam in the second embodiment;

FIG. 17 is a graph illustrating a relationship between the resistance value of the interconnection and the irradiation intensity;

FIG. 18 is a flow chart of the energy beam processing method according to a third embodiment;

FIG. 19 is a table illustrating the threshold values, the scan rates, the standby periods of time and the irradiation intensities of the respective stages of the third embodiment;

FIG. 20A to 21B are time charts illustrating an irradiation of an ion beam in the third embodiment;

FIG. 22 is a table illustrating the threshold values, the scan rates and the standby period of time of the respective stages of a first modification of the third embodiment; and

FIG. 23 is a table illustrating the threshold values, the scan rates and the standby period of time of the respective stages of a second modification of the third embodiment.

### DESCRIPTION OF EMBODIMENTS

It is not always easy to judge that the interconnection has been accurately cut, and often an insufficient cut, an erroneous cut of a lower layer interconnection, etc. take place.

### [a] First Embodiment

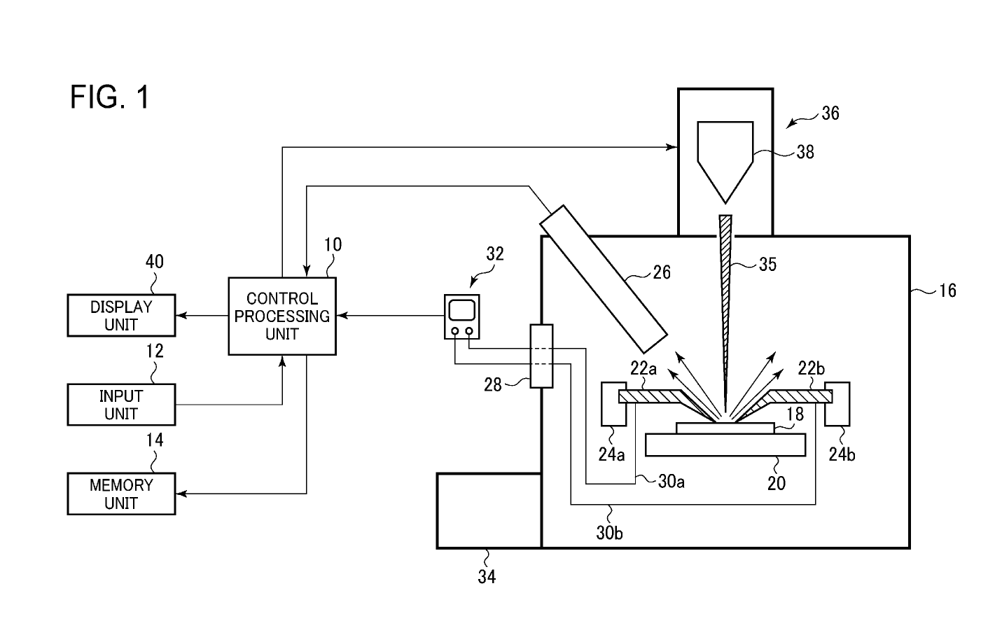

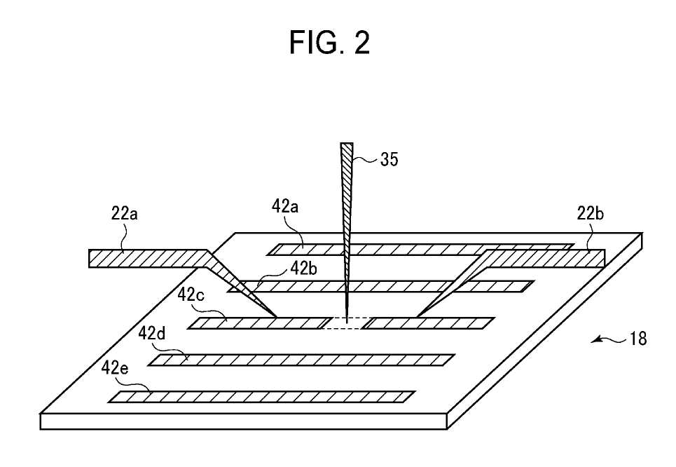

The energy beam processing apparatus and the energy beam processing method according a first embodiment will be described with reference to FIGS. 1 to 10. FIG. 1 is a diagrammatic view of the energy beam processing apparatus according to the present embodiment. FIG. 2 is an enlarged perspective view of a part of the energy beam processing apparatus according to the present embodiment.

First, the energy beam processing apparatus according to the present embodiment will be described with reference to FIGS. 1 and 2.

The energy beam processing apparatus according to the present embodiment uses an FIB (Focused Ion Beam) apparatus, which irradiates focused ion beams.

The energy beam processing apparatus according to the present embodiment includes a control processing unit 10, an input unit 12, a memory unit 14, a chamber 16, a stage 20, probes 22a, 22b, probe positioners 24a, 24b, a secondary electron detector 26, a measurement unit 32, an irradiation unit 36, a display unit 40, etc.

The control processing unit (control unit) 10 controls generally the energy beam processing apparatus according to the present embodiment and makes prescribed processing. As the control processing unit 10, a personal computer or others, for example, is used.

To the control processing unit 10, the input unit 12 with which an operator inputs commands is connected. As the input unit 12, a keyboard, a mouse or others can be used.

To the control processing unit 10, the memory unit 14 is connected. In the memory unit 14, various data, such as measured results, etc., are stored temporarily or consecutively. In the memory unit 14, programs for the control processing unit 10 making prescribed control and processing are installed.

In the chamber 16, the stage 20 for a semiconductor device 18 to be processed is mounted on, the probes 22a, 22b, the probe positioners 24a, 24b supporting the probes 22a, 22b and the secondary electron detector 26 are provided. The probes 22a, 22b measure the resistance value of an interconnection 42c to be cut (see FIG. 2). The probe positioners 24a, 24b support the probes 22a, 22b, and align the probes 22a, 22b. The probe positioners 24a, 24b are controlled by the control unit 10.

A feedthrough 28 is provided in the chamber 16. Through the feedthrough 28, electric wirings 30a, 30b connected to the probes 22a, 22b are led outside the chamber 16 through the feedthrough 28 and connected to the measurement unit (multimeter) 32. The measurement unit 32 measures the resistance value of the interconnection 42c to be cut. One of the input terminals of the measurement unit 32 is electrically connected to one probe 22a via the electric wiring 30a. The other input terminal of the measurement unit 32 is electrically connected to the other probe 22b via the electric wiring 30b.

To the chamber 16, a vacuum exhaust apparatus 34 for making the chamber 16 vacuum state is connected.

Above the table 20, the irradiation unit (lens barrel) 36 for irradiating focused ion beam 35 is provided. The irradiation unit 36 includes an ion source (ion gun) 38, a lens system (not illustrated), a scanning coil (not illustrated) and a blanking mechanism (not illustrated), etc. The ion source 38 generates the ion beam 35 and uses, e.g., a gallium ion source or others. The lens system focuses the ion beam 35 form the ion source 38. The scanning coil (polariscope) controls the irradiation position of the ion beam 35 to scan the ion beam 35. The blanking mechanism turns on and off the ion beam 35. The beam diameter of the ion beam 35 can be suitably set. The beam diameter of the ion beam 35 is set at, e.g., about 5 nm here. The irradiation unit 36 irradiates the ion beam 35 to a part of the interconnection 42c to be cut while scanning the ion beam 35 to shave thinner the part of the interconnection 42c by the sputtering effect to cut the interconnection 42c.

The control processing unit 10 decides a scanning rate of the ion beam 35 in accordance with a resistance value of the interconnection 42c to be cut. The information of the scanning rate decided by the control processing unit 10 is outputted to the irradiation unit 36. The irradiation unit 36 scans the ion beam 35 at the scanning rate decided by the control processing unit 10.

The control processing unit 10 decides a standby period of time from the finish of one scan to the next scan in accordance with the resistance value of the interconnection 42c to be cut. The information of the standby time decided by the control processing unit 10 is outputted to the irradiation unit 36. The irradiation unit 36 stands by for the standby period of time determined in advance by the control processing unit 10 after one scan has been finished, and makes the next scan.

The scan of the ion beam 35 by the irradiation unit 36, and the decision of the scanning rate and the standby period of time by the control processing unit 10 are not synchronized. Accordingly, while the irradiation unit 36 is scanning the ion beam 35, often the control processing unit 10 changes the scanning rate and the standby period of time. When the scanning rate and the standby period of time are changed by the control processing unit 10 in the scan of the ion beam 35 by the irradiation unit 36, the irradiation unit 36 may change the scanning rate in the scan concerned or when the next scan is made. When the standby period of time is changed by the control processing unit 10 while the irradiation unit 36 is scanning the ion beam 35, the irradiation unit 36 stands by for a new standby period of time changed by the control unit 10 after the scan concerned has been completed, and makes the next scan.

The control processing unit 10 decides an irradiation intensity at the time when the irradiation unit 36 scans the ion beam 35. The information of the irradiation intensity decided by the control processing unit 10 is outputted to the irradiation unit 36. In the present embodiment, the irradiation intensity for scanning the ion beam 35 is set at a constant value. The irradiation intensity of the ion beam 35 is, e.g., about times a minimum irradiation intensity of the energy beam processing apparatus according to the present embodiment. The ion beam 35 is not irradiated from the finish of one scan to the start of the next scan.

To the control processing unit 10, the display unit 40 which displays the resistance value of the interconnection to be described later, the proceeding of the processing, etc. is connected. The display unit 40 is, e.g., a CRT, liquid crystal display or others.

The control processing unit 10 can acquire secondary electron images with a secondary electron detector 26. The acquired secondary electron images can be displayed on the display unit 40.

Thus, the energy beam processing apparatus according to the present embodiment is constituted.

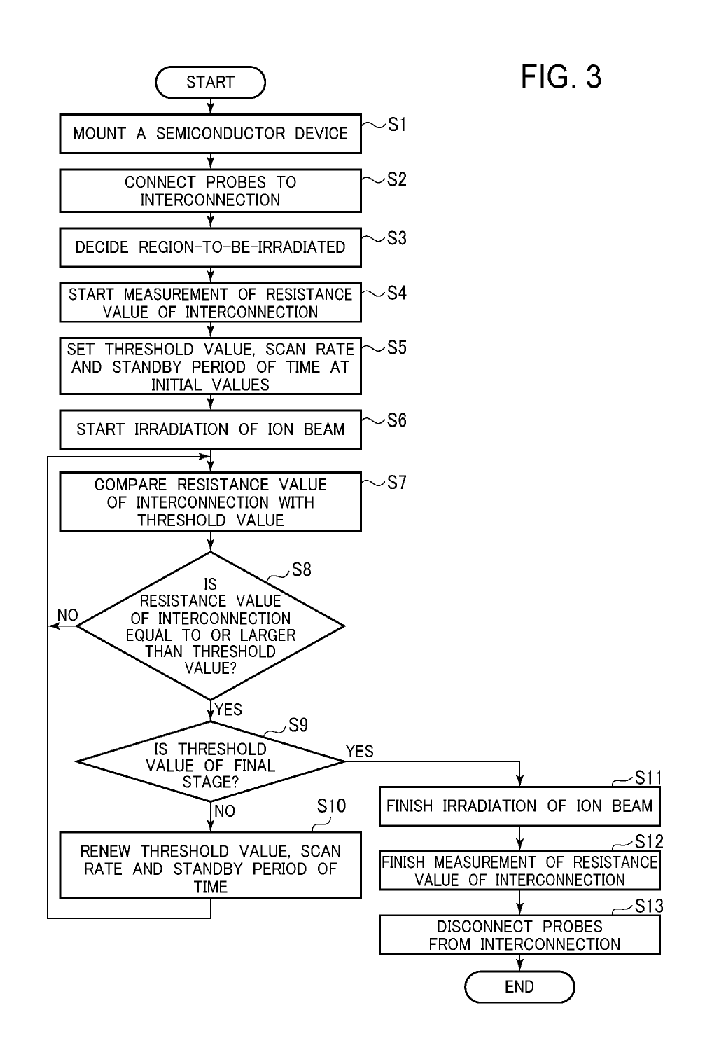

Next, the operation of the energy beam processing apparatus according to the present embodiment and the energy beam processing method according to the present embodiment will be described with reference to FIGS. 1 to 10. FIG. 3 is the flow chart of the energy beam processing method according to the present embodiment.

First, a semiconductor device 18 to be processed is mounted on the stage 20 (Step S1). As illustrated in FIG. 2, interconnections 42a -42e are formed in the semiconductor device. Of the interconnections 42a -42e, an interconnection to be cut is, e.g., the interconnection 42c. The interconnections 42a -42e are formed of, e.g., Cu (copper), Al (aluminum) or others.

Next, as illustrated in FIG. 2, the probes 22a, 22b are connected to the interconnection 42c to be cut (Step S2). Specifically, one probe 22a is connected to one side of the portion of the interconnection 42c to be cut, and to the other side of the portion of the interconnection 42c to be cut, the other probe 22b is connected.

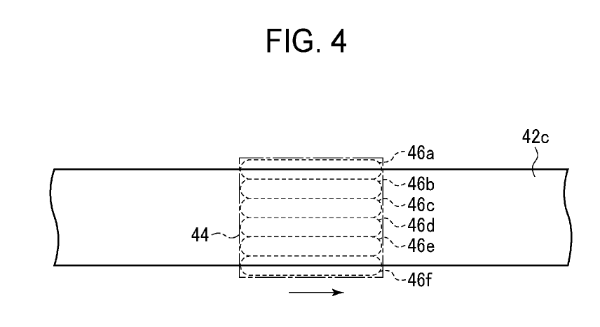

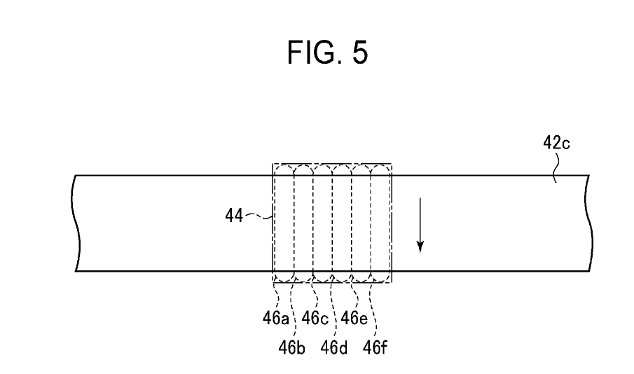

Next, a region-to-be-irradiated (region-to-be-processed, frame-to-be-processed) 44 for the ion beam 35 to be irradiated is decided (Step S3). FIG. 4 is a plan view (Part 1) of an example of a region-to-be-irradiated and partial regions. FIG. 5 is the plan view (Part 2) of an example of a region-to-be-irradiated and partial regions. In FIGS. 4 and 5, the region-to-be-irradiated 44 is indicated by the one-dot chain lines. The dimension of the region-to-be-irradiated 44 along the width of the interconnection 42c may be equal to the width of the interconnection 42c or larger than the width of the interconnection 42c. However, to surely cut the interconnection 42c, it is preferable that the dimension of the region-to-be-irradiated 44 along the width of the interconnection 42c is larger than the width of the interconnection 42c. The dimension of the region-to-be-irradiated 44 along the width of the interconnection 42c here is set larger than the width of the interconnection 42c. The region-to-be-irradiated 44 is set containing a portion of the interconnection 42c to be cut (region-to-be-cut, portion-to-be-cut). The region-to-be-irradiated 44 contains a plurality of partial regions (regions-to-be-scanned) 46a - 46f. In FIGS. 4 and 5, the respective partial regions 46a - 46f are indicated by the broken lines. The respective partial regions 46a - 46f are regions the ion beam 35 is irradiated in one scan. In FIG. 4, the longitudinal direction of the partial regions 46a - 46f is along the longitudinal direction of the interconnection 42c. In FIG. 5, the longitudinal direction of the partial regions 46a - 46f are direction crossing the longitudinal direction of the interconnection 42c, more specifically, is perpendicular to the longitudinal direction of the interconnection 42c.

Then, the measurement of the resistance value of the interconnection 42c to be cut is started (Step S4). The measurement of the resistance value of the interconnection 42c is made by the measurement unit 32. The measurement of the resistance value of the interconnection 42c is continued until the completion of the cut of the interconnection 42c.

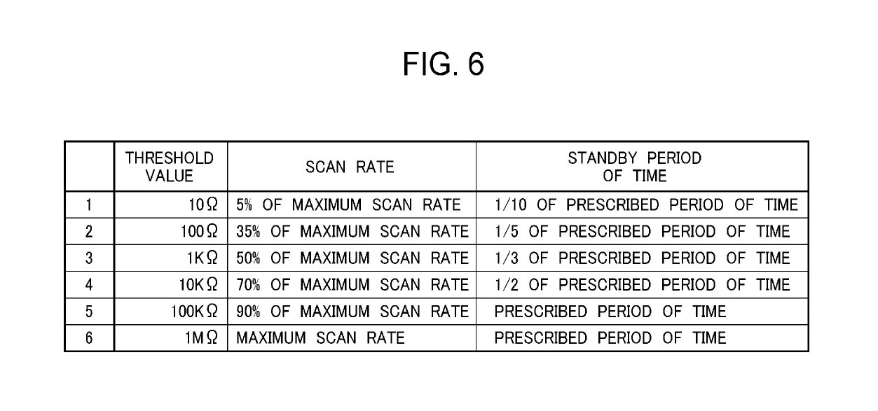

Then, the control processing unit 10 sets the scan rate of the ion beam 35 at the initial value (Step S5). For example, the initial value of the ion beam 35 is set at, e.g., 5% of the maximum scan rate of the energy beam processing apparatus according to the present embodiment (see FIG. 6). The control processing unit 10 sets the standby period of time from the finish of one scan to the start of the next scan at the initial value (Step S5). The initial value of the standby period of time is, e.g., 1/10 of a prescribed period of time (see FIG. 6). The prescribed period of time here is a period of time taken from the time when the control processing unit 10 acquires the resistance value of the interconnection 42c given by the measurement unit 32 to the time when the control processing unit 10 outputs a command of the irradiation stop of the ion beam 35 to the irradiation unit 36. Specifically, such prescribed period of time includes a period of time taken for the control processing unit 10 to acquire the resistance value, a period of time taken to compare the acquired resistance value with a threshold value, and a period of time taken for the processing to stop the ion beam, etc. The control processing unit 10 sets the threshold values to be described later at the initial value (Step S5). The initial value of the threshold value, i.e., the threshold value at the first step is, e.g., 10Ω(see FIG. 6). The control processing unit 10 stores the set threshold values in, e.g., a threshold value memory (not illustrated) provided in the memory unit 14.

Next, the control processing unit 10 commands the irradiation unit 36 to start the irradiation of the ion beam 35 to the region-to-be-irradiated 44 (Step S6). The irradiation of the ion beam 35 to the region-to-be-irradiated 44 is made as follows.

The irradiation unit 36 applies the ion beam 35 to the first partial region 46a of the plural partial regions 46a-46f contained in the region-to-be-irradiated 44 (see FIGS. 4A to 5B). Specifically, the irradiation of the ion beam 35 is started at the start point of the first partial region 46a, and the irradiation point of the ion beam 35 is shifted gradually toward the end point of the scan. When the irradiation point of the ion beam 35 arrives at the end point of the scan in the first partial region 46a, the irradiation of the ion beam 35 is stopped. The arrows in FIGS. 4A to 5B indicate the scan directions. The scan rate is a scan rate decided in advance by the control processing unit 10. At the initial stage, the scan rate is the initial value.

When the scan of the ion beam 35 for the first partial region 46a is completed, the irradiation unit 36 stops the irradiation of the ion beam 35 and stands by for a standby period of time decided in advance by the control processing unit 10.

After the standby period of time decided in advance by the control processing unit 10 has passed, the irradiation unit 36 scans the ion beam 35 over the second partial region 46b adjacent to the first partial region 46a. Specifically, the irradiation of the ion beam 35 is started at the start point of the scan of the second partial region 46b, and the irradiation point of the ion beam 35 is shifted gradually toward the end point of the scan. The irradiation of the ion beam 35 is stopped when the irradiation point of the ion beam 35 arrives at the end point of the scan in the second partial region 46b.

When the scan of the ion beam 35 over the second partial region 46b is completed, the irradiation unit 36 stops the irradiation of the ion beam 35 and stands by for a standby period of time decided in advance by the control processing unit 10.

After the standby period of time decided in advance by the control processing unit 10 has passed, the irradiation unit 36 scans the ion beam 35 over the third partial region 46c adjacent to the second partial region 46b. Specifically, the irradiation of the ion beam 35 is started at the start point of the scan in the third partial region 46c, and the irradiation point of the ion beam 35 is shifted gradually toward the end point of the scan. When the irradiation point of the ion beam 35 arrives at the end point of the scan in the third partial region 46c, the irradiation of the ion beam 35 is stopped.

Hereafter, in the same way, the ion beam 35 is scanned sequentially over the rest partial regions 46d -46f contained in the region-to-be-irradiated 44.

When the scan of the ion beam 35 has been made over all the partial regions 46a -46f contained in the region-to-be-irradiated 44, the ion beam 35 is scanned again in the same way over the respective plural partial regions 46a -46f. The description is made here by means of the example that the region-to-be-irradiated 44 contains six partial regions 46a -46f, but the partial regions contained in the region-to-be-irradiated 44 is not limited to six partial regions. The number of the partial regions may be suitably set, in accordance with the width of the interconnection 42c and the beam diameter of the ion beam 35. When the number of the partial regions contained in the region-to-be-irradiated 44 is n, after the scan over the n-th partial region has been completed, the scan is returned to the first partial region and the scan is made sequentially from the first partial region.

The scan of the ion beam 35 made sequentially over the respective partial regions 46a - 46f is repeated until the interconnection 42c is cut off.

After the scan of the ion beam 35 is started by the irradiation unit 36, i.e., after Step S6, the control processing unit 10 makes the following processing.

That is, the control processing unit 10 compares the resistance value of the interconnection 42c measured by the measurement unit 32 and the threshold value set in advance with each other (Step S7). The threshold value set in advance is stored in the threshold memory (not illustrated) provided in the memory 14.

FIG. 6 is the table of the threshold values, the scan rates and the standby periods of time of the respective stages.

As illustrated in FIG. 6, the threshold value at the first stage is the threshold value at the initial stage, i.e., the initial value, e.g., 10Ω. The threshold value at the second stage is, e.g., 100Ω. The threshold value at the third stage is, e.g., 1 kΩ. The threshold value at the fourth stage is, e.g., 10 kΩ. The threshold value at the fifth stage is, e.g., 100 kΩ. The threshold value at the sixth stage is the threshold value at the final stage, e.g., 1 MΩ.

The table illustrated in FIG. 6 is stored in, e.g., the memory unit 14.

When the resistance value of the interconnection 42c is smaller than the threshold value set in advance (Step S8), the processing is returned to Step S7.

When the resistance value of the interconnection 42c is equal to or larger than the threshold value set in advance (Step S8), the control processing unit 10 confirms whether or not the threshold value concerned is the threshold value at the final stage (Step S9).

When the threshold value concerned is not the threshold value at the final stage, the control processing unit 10 renews the threshold value, the scan rate and the standby period of time as follows, based on the measured resistance value of the interconnection 42c (Step S10).

When the measured resistance value of the interconnection 42c is larger than the threshold value at the first stage, and lower than or equal to the threshold value at the second stage, the control processing unit 10 sets the threshold value at the threshold value of the second stage. In this case, the control processing unit 10 set the scan rate at the scan rate of the second stage. For example, as illustrated in FIG. 6, the scan rate at the second stage is, e.g., about 35% of the maximum scan rate of the energy beam processing apparatus according to the present embodiment. Also in this case, the control processing unit 10 sets the standby period of time at the standby period of time of the second stage. As illustrated in FIG. 6, the standby period of time of the second stage is, e.g., ⅕ of, e.g., the prescribed period of time described above.

When the measured resistance value of the interconnection 42c is larger than the threshold value of the second stage, and lower than or equal to the threshold value of the third stage, the control processing unit 10 sets the threshold value at the threshold value of the third stage. In this case, the control processing unit 10 sets the scan rate at the scan rate of the third stage. For example, as illustrated in FIG. 6, the scan rate of the third stage is set at, e.g., 50% of the maximum scan rate of the energy beam processing apparatus. In this case, the control processing unit 10 sets the standby period of time at the standby period time of the third stage. For example, as illustrated in FIG. 6, the standby period of time of the third stage is, e.g., about ⅓ of the prescribed period of time described above.

When the measured resistance value of the interconnection 42c is larger than the threshold value of the third stage, and lower than or equal to the threshold value of the fourth stage, the control processing unit 10 sets the threshold value at the threshold value of the fourth stage. In this case, the control processing unit sets the scan rate at the scan rate of the fourth stage. For example, as illustrated in FIG. 6, the scan rate of the fourth stage is, e.g., 70% of the maximum scan rate of the energy beam processing apparatus. Also, in this case, the control processing unit 10 sets the standby period of time at the standby period of time of the fourth stage. For example, as illustrated in FIG. 6, the standby period of time of the fourth stage is, e.g., ½ of the prescribed period of time described above.

When the measured resistance value of the interconnection 42c is large than the threshold value of the fourth stage, and lower than or equal to the threshold value of the fifth stage, the control processing unit 10 sets the threshold value at the threshold value of the fifth stage. In this case, the control processing unit 10 sets the scan rate at the scan rate of the fifth stage. For example, as illustrated in FIG. 6, the scan rate of the fifth stage is, e.g., 90% of the maximum scan rate of the energy beam processing apparatus. Also, in this case, the control processing unit 10 sets the standby period of time at the standby period of time of the fifth stage. As illustrated in FIG. 6, the standby period of time of the fifth stage is, e.g., the prescribed period of time described above.

When the measured resistance value of the interconnection 42c is larger than the threshold value of the fifth stage, and lower than or equal to the threshold value of the sixth stage, the control processing unit 10 sets the threshold value at the threshold value of the sixth stage, i.e., the threshold value of the final stage. In this case, the control processing unit 10 set the scan rate at the scan rate of the sixth stage. For example, as illustrated in FIG. 6, the scan rate of the sixth stage is the maximum scan rate of the energy beam processing apparatus. In this case, the control processing unit 10 sets the standby period of time at the standby period of time of the sixth stage. As illustrated in FIG. 6, the standby period of time of the sixth stage is, e.g., prescribed period of time described above.

The control processing unit 10 stores the thus decided threshold values, e.g., in the threshold memory (not illustrated) provided in the memory unit 14. The control processing unit 10 outputs the information of the decided scan rate and standby period of time to the irradiation unit 36. When the scan rate and the standby period of time are renewed by the control processing unit 10, the irradiation unit 36 scans the energy beam 35 at the renewed scan rate and standby period of time.

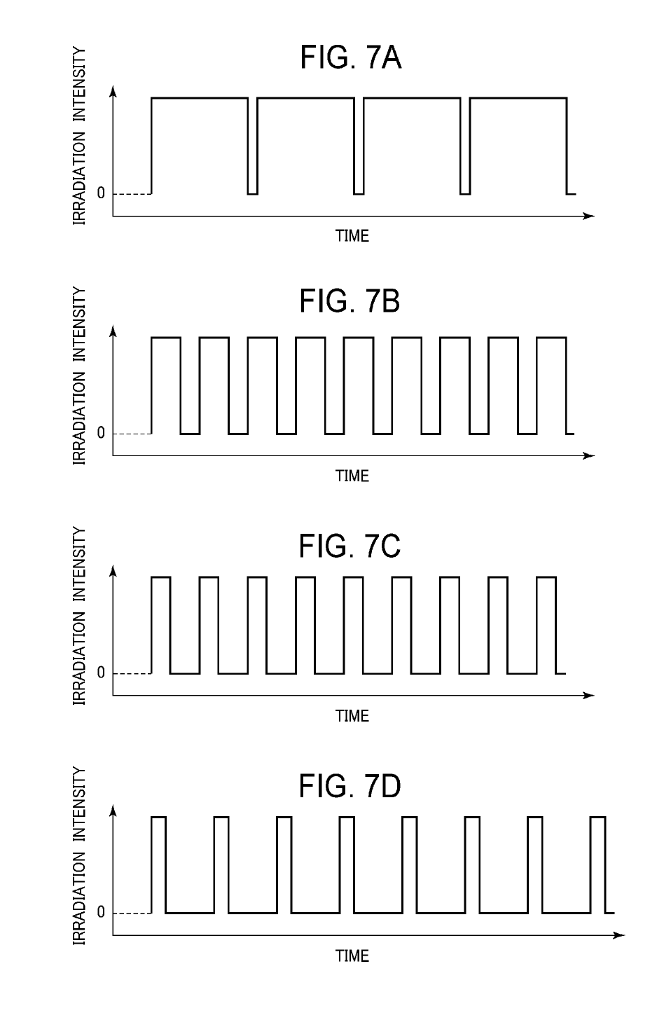

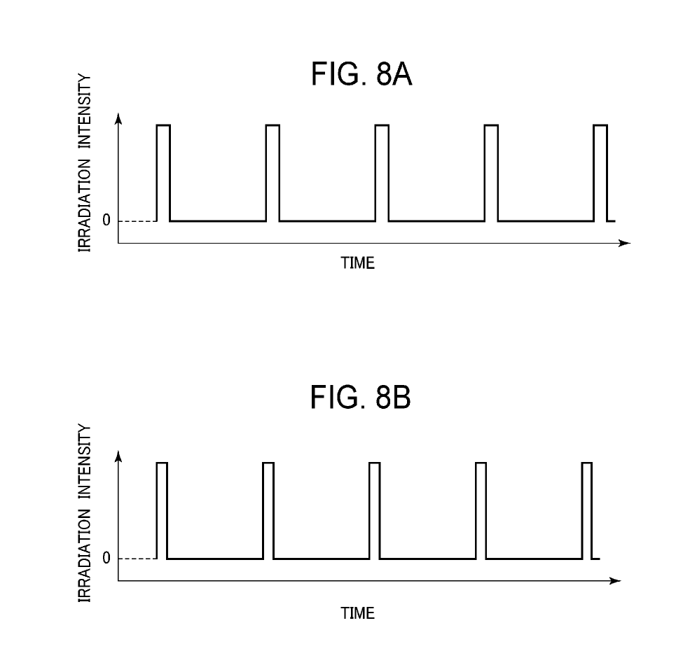

FIGS. 7A to 8B are the time charts illustrating the irradiation of the ion beam. On the horizontal axis of FIGS. 7A to 8B, time is taken, and the irradiation intensity of the ion beam is taken on the vertical axis of FIGS. 7A to 8B. FIG. 7A illustrates the time chart of the first stage. FIG. 7B illustrates the time chart of the second stage. FIG. 7C illustrates the time chart of the third stage. FIG. 7D illustrates the time chart of the fourth stage. FIG. 8A illustrates the time chart of the fifth stage. FIG. 8B illustrates the time chart of the sixth stage.

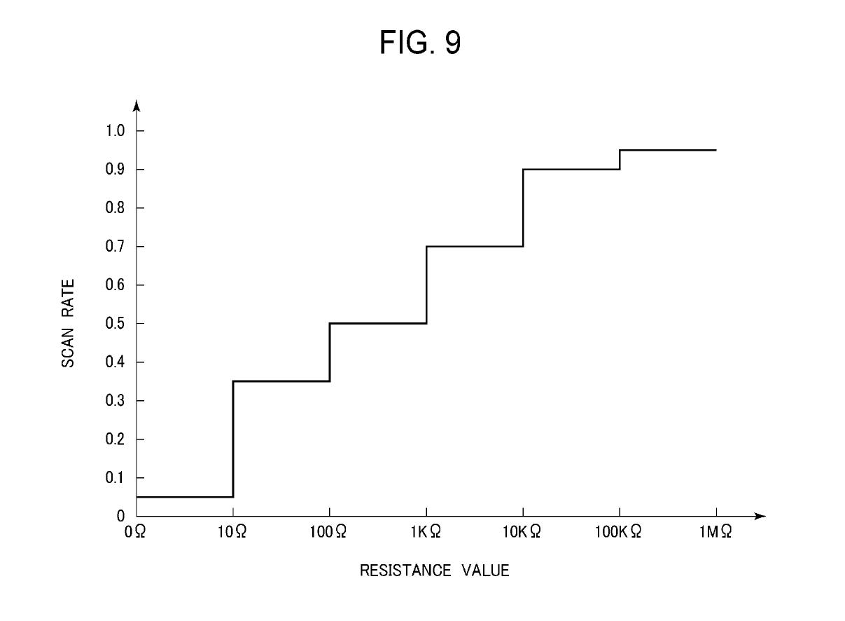

FIG. 9 is the graph of the relationship between the resistance value of the interconnection and the scan rate. On the horizontal axis of FIG. 9, the resistance value of the interconnection is taken. On the vertical axis of FIG. 9, the scan rate is taken. In FIG. 9, the maximum scan rate of the energy beam processing apparatus according to the present embodiment is 1.0.

As illustrated in FIG. 9, as the measured resistance value of the interconnection 42c becomes larger, the scan rate increases.

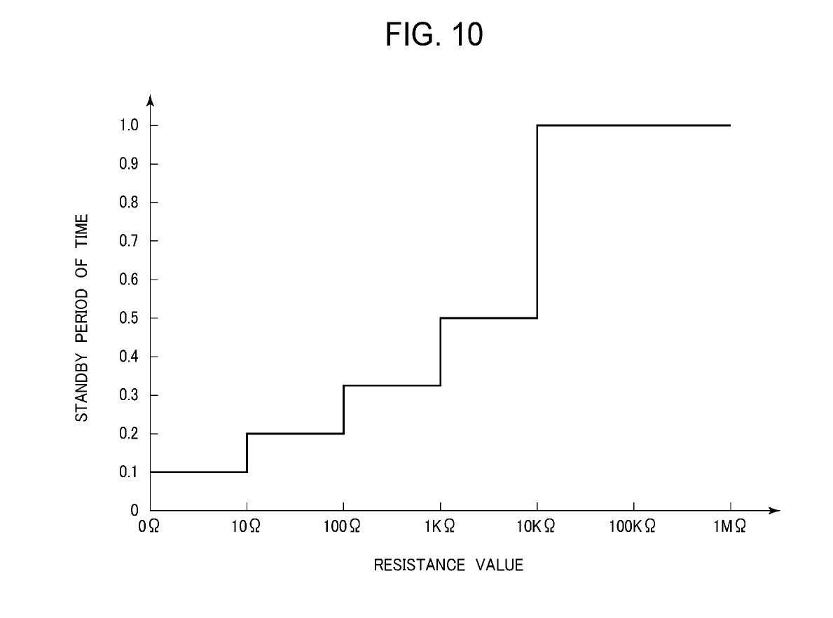

FIG. 10 is the graph illustrating the relationship between the resistance value of the interconnection and the standby period of time. On the horizontal axis of FIG. 10, the resistance value of the interconnection is taken. On the vertical axis of FIG. 10, the standby period of time is taken. In FIG. 10, the length of the prescribed period of time described above is 1.0.

As illustrated in FIG. 10, as the measured resistance value of the interconnection 42c becomes larger, the standby period of time is longer.

The control processing unit 10 repeats the processing of Step S7 and the followings steps after the threshold value, the scan rate and the standby period time are renewed, i.e., after Step 10.

For the following reason, the scan rate decreases as the measured resistance value of the interconnection 42c is smaller. That is, as the scan rate is lower, the interconnection 42 is more quickly thinned in the scan concerned. Accordingly, decreasing the scan rate contributes to the improvement of the throughput of cutting the interconnection 42c. On the other hand, while the resistance value of the interconnection 42c is small, the possibility of the interconnection 42c being cut off in the scan concerned is low. Accordingly, the possibility of excessive irradiation of the ion beam being made to the semiconductor device 18 in the scan concerned even when the scan is made at low rate is low. For this reason, the scan rate is set lower as the measured resistance value of the interconnection 42c is smaller.

For the following reason, the scan rate is set higher as the measured resistance value of the interconnection 42c is larger. That is, when the resistance value of the interconnection 42c becomes larger, the possibility of the interconnection 42c being cut off in the scan concerned is higher. Making the scan at high rate contributes to the decrease of damaging the semiconductor device 18 when the interconnection 42c has been cut by the scan concerned. For this reason, the scan rates is set higher as the measured resistance values of the interconnection 42c is larger.

For the following reason, the standby period time from the finish of one scan to the start of the next scan is set shorter as the measured resistance value of the interconnection 42c is smaller. That is, while the resistance value of the interconnection 42c is small, the possibility of the interconnection 42c being cut off by the scan concerned is low. Accordingly, even when the next scan is started after a short standby period of time, the possibility of the semiconductor device 18 being damaged is low. On the other hand, setting short the standby period of time from the finish of one scan to the start of the next scan contributes to improving the throughput. For this reason, the standby period of time from the finish of one scan to the start of the next scan is set shorter as the measured resistance value of the interconnection 42c is smaller.

For the following reason, the standby period of time from the finish of one scan to the start of the next scan is set longer as the measured resistance value of the interconnection 42c becomes larger. That is, when the resistance value of the interconnection 42c is large, the possibility of the interconnection 42c being cut off by the scan concerned is high. When the next scan is made even when the interconnection 42c cut off at the finish of one scan, there is a risk that the lower layer interconnections, etc. might be damaged. The standby period of time from the finish of one scan to the start of the next scan is made longer as the resistance value of the interconnection 42c becomes larger, whereby the next scan can be prevented even when the interconnection 42c has been cut off. For this reason, the standby period of time from the finish of one scan to the start of the next scan is set longer as the measured resistance value of the interconnection 42c becomes larger.

When the measured resistance value of the interconnection 42c exceeds the threshold value of the sixth stage, i.e., the threshold value of the final stage (Step S9), the control processing unit 10 judges that the interconnection 42c has been cut off. In this case, the control processing unit 10 controls the irradiation unit 36 to stop the irradiation of the ion beam 35 (Step S11). Thus, the irradiation of the ion beam 35 to the region-to-be-irradiated 44 is completed.

Next, the measurement of the resistance value of the interconnection 42c by the measurement unit 32 is finished (Step S12)

Next, the connection between the probes 22a, 22b and the interconnection 42c is released (Step S13).

Thus, the energy beam processing method according to the present embodiment is completed.

As described above, according to the present embodiment, the scan rate and the standby period of time are set in accordance with the resistance value of the interconnection 42c. At the stage where the resistance value of the interconnection 42c is low, the scan rate is low, which can accelerate the cut of the interconnection 42c. At the stage where the resistance value of the interconnection 42c is low, the standby period of time is short, whereby the throughput can be high. On the other hand, at the stage where the resistance value of the interconnection 42c is large, the scan rate is high, whereby damaging the lower layer interconnections, etc. can be suppressed. At the stage where the resistance value of the interconnection 42c is large, the standby period of time is long, whereby the operation of the next scan even when the interconnection 42c being cut off by one scan can be prevented. Thus, erroneous cutting off the lower layer interconnections and damaging the lower layer interconnections can be prevented. According to the present embodiment, without impairing the reliability, the interconnection 42c can be cut with a high throughput.

### A First Modification

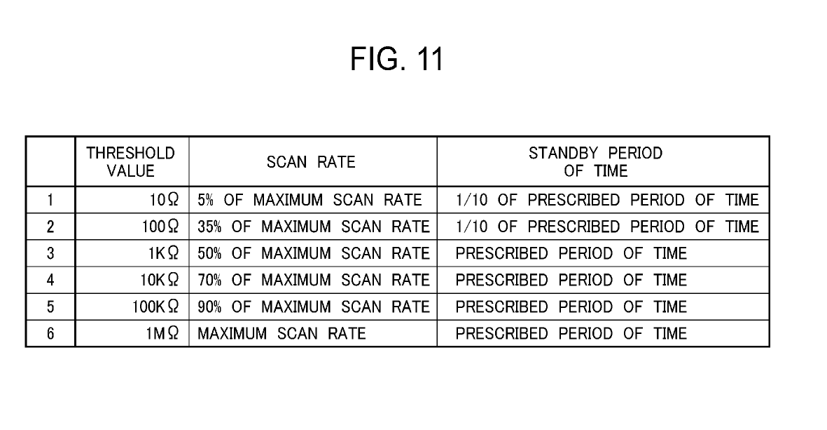

Next, the energy beam processing apparatus and processing method according to a first modification of the present embodiment will be described with reference to FIG. 11. FIG. 11 is the table of the threshold values, the scan rates and the standby periods of time of the respective stages of the present modification.

As illustrated in FIG. 11, in the present modification, the threshold values of the respective stages are set as in the first embodiment described with reference to FIG. 6. The scan rates of the respective stages are also set as in the first embodiment described above with reference to FIG. 6.

On the other hand, in the present modification, the standby period of time has two kinds. That is, in the irradiation of the first stage and the second stage, the standby periods of time are, e.g., 1/10 of the prescribed period of time described above. In the irradiation of the third stage to the sixth stage, the prescribed period of time described above is used.

The table of FIG. 11 is stored in, e.g., the memory unit 14.

The combination of the threshold values, the scan rates and the standby periods of time of the respective stages can be set as in the present modification.

### A Second Modification

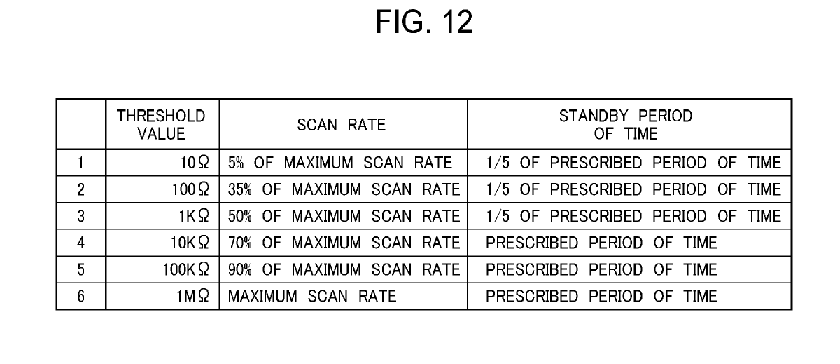

The energy beam processing apparatus and processing method according to a second modification of the present embodiment will be described with reference to FIG. 12. FIG. 12 is the table of the threshold values, the scan rates and the standby periods of time of the respective stages of the present modification.

As illustrated in FIG. 12, in the present modification, the threshold values of the respective stages are set as in the first embodiment described above with reference to FIG. 6. The scan rates of the respective stages are set also as in the first embodiment described above with reference to FIG. 6.

On the other hand, in the present modification, the standby period of time has two kinds. That is, in the irradiation from the first stage to the third stage, the standby periods of time are, e.g., ⅕ of the prescribed period of time described above. In the irradiation from the fourth stage to the sixth stage, the prescribed period of time described above is used.

The table of FIG. 12 is stored in, e.g., the memory unit 14.

The combination of the threshold values, the scan rates and the standby periods of time of the respective stages can be set as in the present modification.

### [b] Second Embodiment

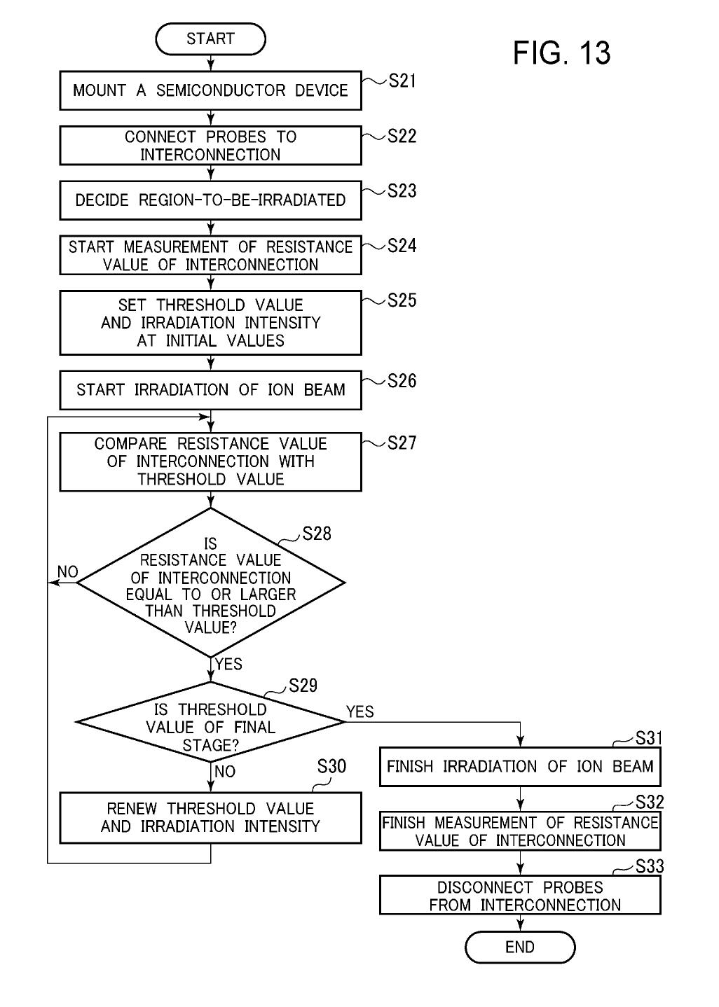

The energy beam processing apparatus and processing method according to a second embodiment will be described with reference to FIG. 1 and FIGS. 13 to 17. FIG. 13 is the flow chart of the energy beam processing method according to the present embodiment. The same members of the present embodiment as those of the energy beam processing apparatus and processing method according to the first embodiment illustrated in FIGS. 1 to 12 are represented by the same reference numbers not to repeat or to simplify the description.

The energy beam processing apparatus according to the present embodiment is characterized mainly in that the irradiation intensity of the ion beam 35 is changed in accordance with a measured resistance value of the interconnection 42c.

The control processing unit 10 decides the irradiation intensity of the ion beam 35 in accordance with a resistance value of the interconnection 42c to be cut. The information of the irradiation intensity decided by the control processing unit 10 is outputted to the irradiation unit 36. The irradiation unit 36 scans the ion beam 35 at the irradiation intensity decided by the control processing unit 10. The scan of the ion beam 35 by the irradiation unit 36, and the decision of the irradiation intensity by the control processing unit 15 are not synchronized. Accordingly, the change of the irradiation intensity by the control processing unit 10 is often made while the irradiation unit 36 is scanning the ion beam 35. When the change of the irradiation intensity by the control processing unit 10 is made during the scan of the ion beam 35 by the irradiation unit 36, the irradiation unit 36 may change the irradiation intensity during the scan concerned or from the start of the next scan. As in the energy beam processing apparatus according to the first embodiment, from the finish of one scan to the start of the next scan, the ion beam 35 is not irradiated.

The control processing unit 10 decides the scan rate for the irradiation unit 36 scanning the ion beam 35. The information of the scan rate decided by the control processing unit 10 is outputted to the irradiation unit 36. In the present embodiment, the scan rate for the scanning the ion beam 35 is a constant value (fixed value). Specifically, the scan rate of the ion beam 35 is, e.g., 50% of the maximum scan rate of the energy beam processing apparatus according to the present embodiment.

The control processing unit 10 decides a standby period of time from the finish of one scan to the start of the next scan. The information of the standby period of time decided by the control processing unit 10 is outputted to the irradiation unit 36. After one scan has been completed, the irradiation unit 36 stands by for a standby period of time decided in advance by the control processing unit 10 and starts the next scan. In the present embodiment, the standby period of time is a constant value (fixed value). Specifically, in the present embodiment, the standby period of time is, e.g., the prescribed period of time described above.

Thus, the energy beam processing apparatus according to the present embodiment is constituted.

Next, the operation of the energy beam processing apparatus according to the present embodiment and the energy beam processing method according to the present embodiment will be descried with reference to FIG. 1, FIG. 2 and FIGS. 13 to 17. FIG. 13 is the flow chart of the energy beam processing method according to the present embodiment.

First, the step of mounting the semiconductor device 18 (Step S21) to the step of starting the measurement of the resistance value of the interconnection 42c (Step S24) are the same as Steps S1-S4 of the energy beam processing method according to the first embodiment described above with reference to FIG. 3, and their description will not be repeated.

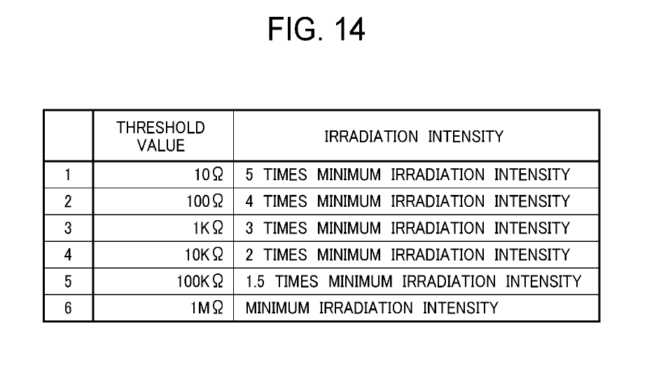

Next, the control processing unit 10 sets the irradiation intensity of the ion beam 35 at the initial value (Step S25). The initial value of the irradiation intensity of the ion beam 35 is a value of, e.g., 5 times the minimum irradiation intensity of the energy beam processing apparatus according to the present embodiment (see FIG. 14). The control processing unit 10 sets the threshold value at the initial value (Step S25). The initial value of the threshold value, i.e., the threshold value of the first stage is, e.g., 10Ω (see FIG. 14). The control processing unit 10 stores the set threshold value in, e.g., the threshold memory (not illustrated) provided in the memory unit 14.

Then, in the same way as in Step S6 of the energy beam processing method according to the first embodiment described above with reference to FIG. 3, the control processing unit 10 commands the irradiation unit 36 to start the irradiation of the ion beam 35 to the region-to-be-irradiated 44 (Step S26).

After the irradiation of the ion beam 35 is started by the irradiation unit 36, i.e., in the steps following Step S26, the control processing unit 10 makes the following processing.

That is, in the same way as in Step S7 of the energy beam processing apparatus according to the first embodiment described above with reference to FIG. 3, the control processing unit 10 compares the resistance value of the interconnection 42c measured by the measurement unit 32 with the preset threshold value (Step S27).

FIG. 14 is the table of the threshold values and the irradiation intensities of the respective stages.

As illustrated in FIG. 14, the threshold values of the respective stages are the same as the threshold values of the respective stage of the energy beam processing method according to the first embodiment described above with reference to FIG. 6.

When the resistance value of the interconnection 42c is smaller than the preset threshold value (Step S28), the processing returns to Step S27.

On the other hand, when the resistance value of the interconnection 42c is equal to or larger than the preset threshold value (Step S28), the control processing unit 10 confirms whether or not the threshold value concerned is the threshold value of the final stage (Stage S29).

When the threshold value concerned is not the threshold value of the final stage, the control processing unit 10 renews the threshold value as follows, based on the measured resistance value of the interconnection 42c (Step S30).

When the measured resistance value of the interconnection 42c is larger than the threshold value of the first stage, and equal to or smaller than the threshold value of the second stage, the control processing unit 10 sets the threshold value at the threshold value of the second stage. In this case, the control processing unit 10 sets the irradiation intensity of the energy beam 35 at the irradiation intensity of the second stage. For example, as illustrated in FIG. 14, the irradiation intensity of the second stage is, e.g., about 4 times the minimum irradiation intensity of the energy beam processing apparatus according to the present embodiment.

When the measured resistance value of the interconnection 42c is larger than the threshold value of the second stage, and equal to or smaller than the threshold value of the third stage, the control processing unit 10 sets the threshold value at the threshold value of the third stage. In this case, the control processing unit 10 sets the irradiation intensity of the energy beam 35 at the irradiation intensity of the third stage. As illustrated in FIG. 14, the irradiation intensity of the third stage is the intensity, e.g., of 3 times the minimum irradiation intensity of the energy beam processing apparatus.

When the measured resistance value of the interconnection 42c is larger than the threshold value of the third stage, and equal to or smaller than the threshold value of the fourth stage, the control processing unit 10 sets the threshold value at the threshold value of the fourth stage. In this case, the control processing unit 10 sets the irradiation intensity of the energy beam 35 at the irradiation intensity of the fourth stage. For example, as illustrated in FIG. 14, the irradiation intensity of the fourth stage is, e.g., twice the minimum irradiation intensity of the energy beam processing apparatus.

When the measured resistance value of the interconnection 42c is larger than the threshold value of the fourth stage, and equal to or smaller than the threshold value of the fifth stage, the control processing unit 10 sets the threshold value at the threshold value of the fifth stage. In this case, the control processing unit 10 sets the irradiation intensity of the energy beam 35 at the irradiation intensity of the fifth stage. For example, as illustrated in FIG. 14, the irradiation intensity of the fifth stage is, e.g., 1.5 times the minimum irradiation intensity of the energy beam processing apparatus.

When the measured resistance value of the interconnection 42c is larger than the threshold value of the fifth stage, and equal to or smaller than the threshold value of the sixth stage, the control processing unit 10 sets the threshold value at the threshold value of the sixth stage, i.e. the threshold value of the final stage. In this case, the control processing unit 10 sets the irradiation intensity of the energy beam 35 at the irradiation intensity of the sixth stage. As illustrated in FIG. 14, the irradiation intensity of the sixth stage is, e.g., the minimum irradiation intensity of the energy beam processing apparatus.

The control processing unit 10 stores the thus-decided threshold value, e.g., in the threshold memory (not illustrated) provided in the memory unit 14. The control processing unit 10 outputs the information of the decided irradiation intensity to the irradiation unit 36. When the irradiation intensity is renewed by the control processing unit 10, the irradiation unit 36 scans the energy beam 35 at the renewed irradiation intensity.

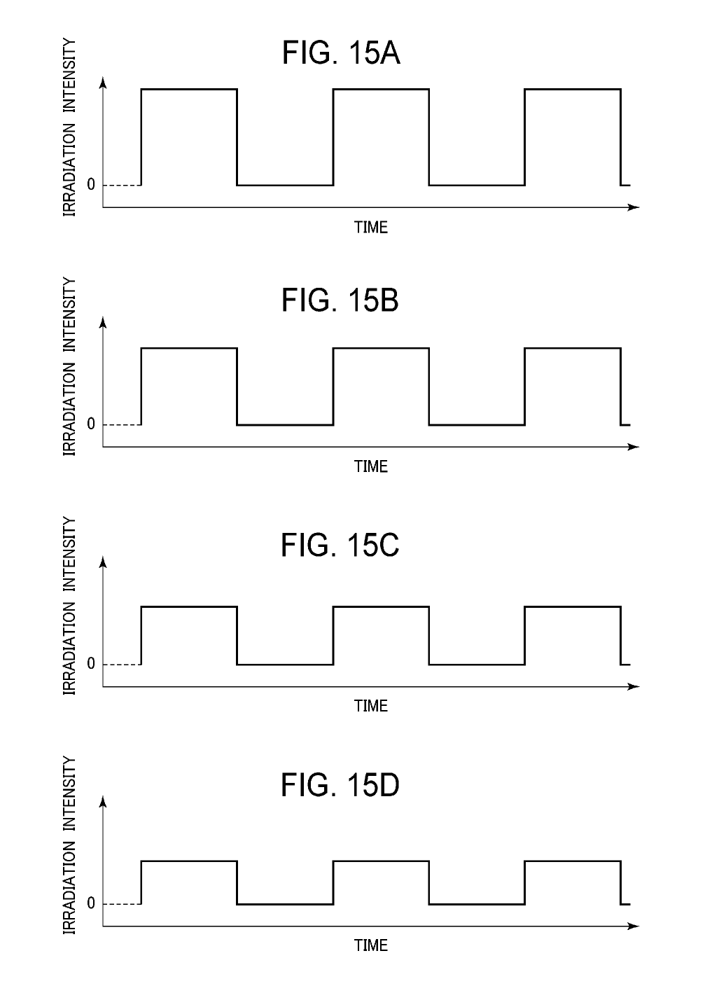

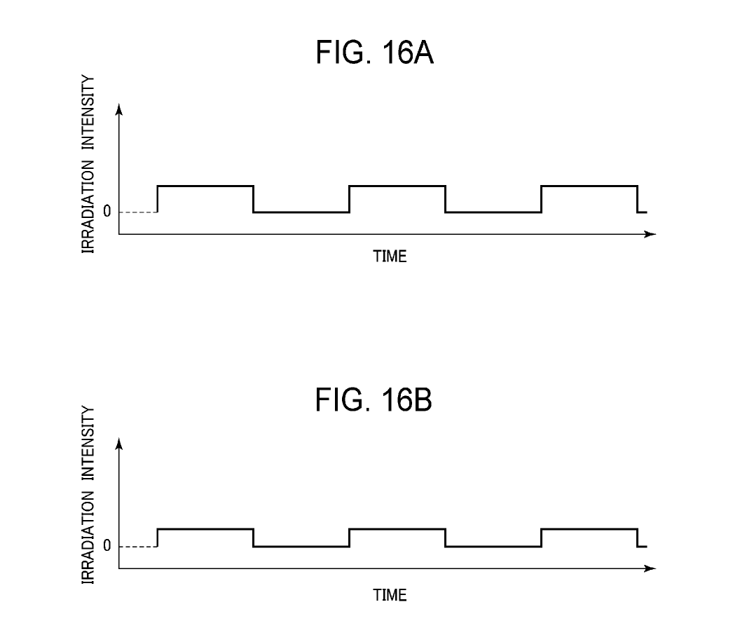

FIGS. 15A to 16B are the time charts of the irradiation of the ion beam. On the horizontal axis in FIGS. 15A to 16B, time is taken, and on the vertical axis in FIGS. 15A to 16B, the irradiation intensity of the ion beam is taken. FIG. 15A is the time chart of the first stage. FIG. 15B is the time chart of the second stage. FIG. 15C is the time chart of the third stage. FIG. 15D is the time chart of the fourth stage. FIG. 16A is the time chart of the fifth stage. FIG. 16B is the time chart of the sixth stage.

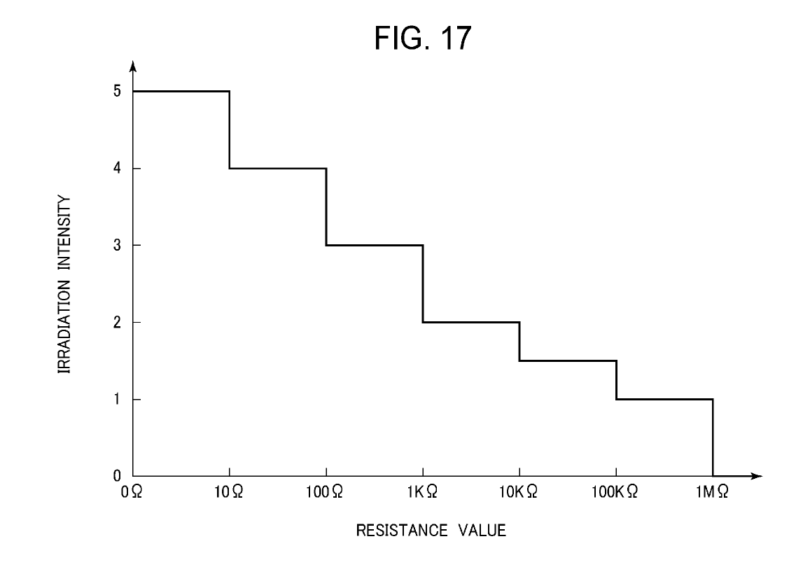

FIG. 17 is the graph illustrating the relationship between the resistance value of the interconnection and the irradiation intensity. On the horizontal axis in FIG. 17, the resistance value of the interconnection is taken. On the vertical axis in FIG. 17, the irradiation intensity is taken. In FIG. 17, the minimum irradiation intensity of the energy beam processing apparatus according to the present embodiment is 1.0.

As illustrated in FIG. 17, as the measured resistance value of the interconnection 42c becomes larger, the irradiation intensity is lower.

After the threshold value and the irradiation intensity have been renewed, i.e., after Step S30, the control processing unit 10 repeats the processing following Step S27.

For the following reason, the irradiation intensity is increased as the measured resistance value of the interconnection 42c is smaller. That is, as the irradiation intensity is higher, the interconnection 42c is thinned more quickly in the scan concerned. Accordingly, increasing the irradiation intensity contributes to improving the throughput. On the other hand, while the resistance value of the interconnection 42c is small, the possibility of the interconnection 42c being cut off by the scan concerned is low. Accordingly, the possibility of excessive irradiation of the ion beam being made to the semiconductor device 18 in the scan concerned even when the irradiation is made with a high irradiation intensity is low. For this reason, the irradiation intensity is set higher as the measured resistance value of the interconnection 42c is smaller.

For the following reason, the irradiation intensity is set lower as the measured resistance value of the interconnection 42c is larger. That is, when the resistance value of the interconnection 42c becomes high, the possibility of the interconnection 42c being cut off by the scan concerned is higher. The irradiation with a low irradiation intensity contributes to decreasing damaging the semiconductor device 18 when the interconnection 42c is cut off by the scan concerned. For this reason, the irradiation intensity is set low as the measured resistance value of the interconnection 42c becomes larger.

When the measured resistance value of the interconnection 42c exceeds the threshold value of the sixth stage, i.e., the threshold value of the final stage (Step S29), the control processing unit 10 judges that the interconnection 42c has been cut off. In this case, the control processing unit 10 controls the irradiation unit 36 to stop the irradiation of the ion beam 35 (Step S31). Thus, the irradiation of the ion beam 35 to the region-to-be-irradiated 44 is finished.

Next, the measurement of the resistance value of the interconnection 42c by the measurement unit 32 is finished (Step S32).

Next, the probes 22a, 22b and the interconnection 42c is disconnected (Steps S33).

Thus, the energy beam processing method according to the present embodiment is completed.

As described above, according to the present embodiment, the irradiation intensity of the ion beam 35 is set in accordance with the resistance value of the interconnection 42c. The irradiation intensity of the ion beam 35 is high at the stage that the resistance value of the interconnection 42c is low, which allows the cut of the interconnection 42c to be accelerated. On the other hand, at the stage that the resistance value of the interconnection 42c becomes larger, the irradiation intensity is low, which can prevent the lower layer interconnections from being damaged, and can prevent the erroneous cut off the lower layer interconnections, etc. Thus, also according to the present embodiment, the interconnection 42c can be cut off with high throughputs without impairing the reliability.

### [c] Third Embodiment

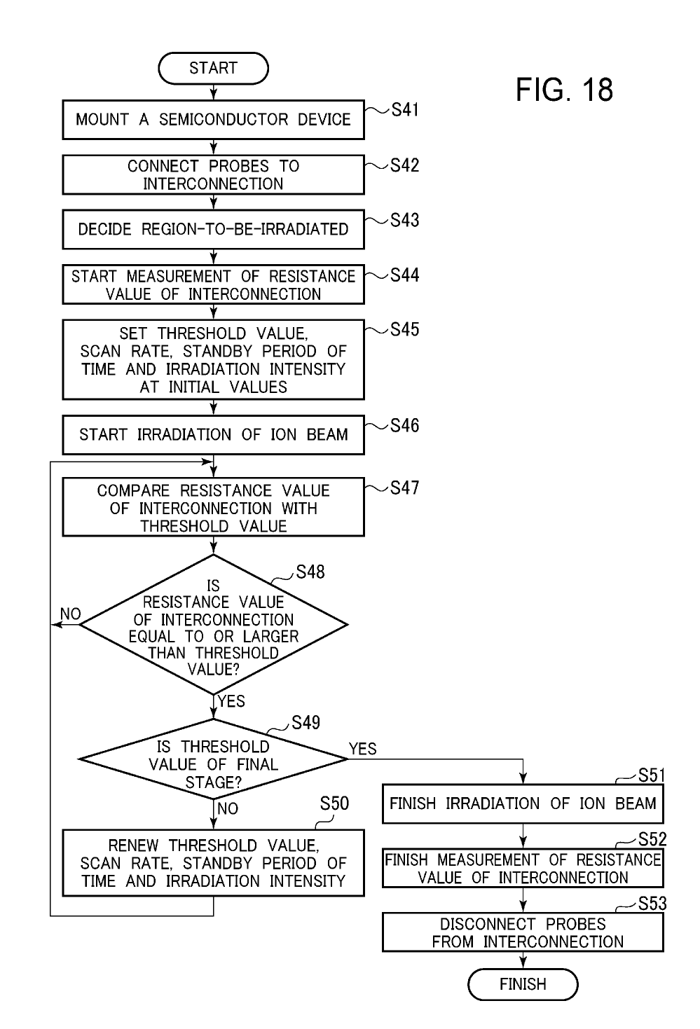

The energy beam processing apparatus and processing method according to a third embodiment will be described with reference to FIG. 1 and FIGS. 18 to 21. FIG. 18 is the flow chart of the energy beam processing method according to the present embodiment. The same members of the present embodiment as those of the energy beam processing apparatus and the processing method according to the first or the second embodiment illustrated in FIGS. 1 to 17 are represented by the same reference numbers not to repeat or to simplify the description.

The energy beam processing apparatus according to the present embodiment is characterized mainly in that the scan rate, the standby period of time and the irradiation intensity of the ion beam 35 are changed in accordance with the measured resistance value of the interconnection 42c.

The control processing unit 10 decides the scan rate of the ion beam 35 in accordance with the resistance value of the interconnection 42c to be cut off. The information of the scan rate decided by the control processing unit 10 is outputted to the irradiation unit 36. The irradiation unit 36 scans the ion beam 35 at the scan rate decided by the control processing unit 10.

The control processing unit 10 decides the irradiation intensity of the ion beam 35 in accordance with the resistance value of the interconnection 42c to be cut off. The information of the irradiation intensity decided by the control processing unit 10 is outputted to the irradiation unit 36. The irradiation unit 36 scans the ion beam 35 with the irradiation intensity decided by the control processing unit 10.

The control processing unit 10 decides the standby period of time (standby time, waiting time) from the completion of one scan to the start of the next scan in accordance with the resistance value of the interconnection 42c to be cut off. The information of the standby period of time decided by the control processing unit 10 is outputted to the irradiation unit 36. After one scan has been completed, the irradiation unit 36 starts the next scan after the standby period time decided in advance by the control processing unit 10.

The scan of the ion beam 35 by the irradiation unit 36, and the decision of the scan rate, the irradiation intensity and the standby period of time by the control processing unit 10 are not synchronized. Accordingly, while the irradiation unit 36 is scanning the ion beam 35, often the control processing unit 10 changes the scan rate, the irradiation intensity and the standby period of time. When the control processing unit 10 changes the scan rate while the irradiation unit 36 is scanning the ion beam 35, the irradiation unit 36 may change the scan rate in the scan concerned or may change the scan rate from the start of the next scan. When the control processing unit 10 changes the irradiation intensity while the irradiation unit 36 is scanning the ion beam 35, the irradiation unit 36 may change the irradiation intensity in the scan concerned or may change the irradiation intensity from the start of the next scan. When the control processing unit 10 changes the standby period of time while the irradiation unit 36 is scanning the ion beam 35, the irradiation unit 36, after the scan concerned has been completed, stands by for a new standby period of time changed by the control processing unit 10 and makes the next scan.

As in the energy beam processing apparatus according to the first embodiment, from the completion of one scan to the start of the next scan, the irradiation of the ion beam 35 is not made.

Thus, the energy beam processing apparatus according to the present embodiment is constituted.

Next, the operation of the energy beam processing apparatus according to the present embodiment and the energy beam processing method according to the present embodiment will be described with reference to FIGS. 1, 2, 9, 10, 17 and FIGS. 18 to 21. FIG. 18 is the flow chart of the energy beam processing method according to the present embodiment.

First, the steps of mounting the semiconductor device 18 (Step S41) to the step of starting the measurement of the resistance value of the interconnection 42c (Step S44) are the same as the Step S1-S4 of the energy beam processing method according to the first embodiment described above with reference to FIG. 3, and their description will not be repeated.

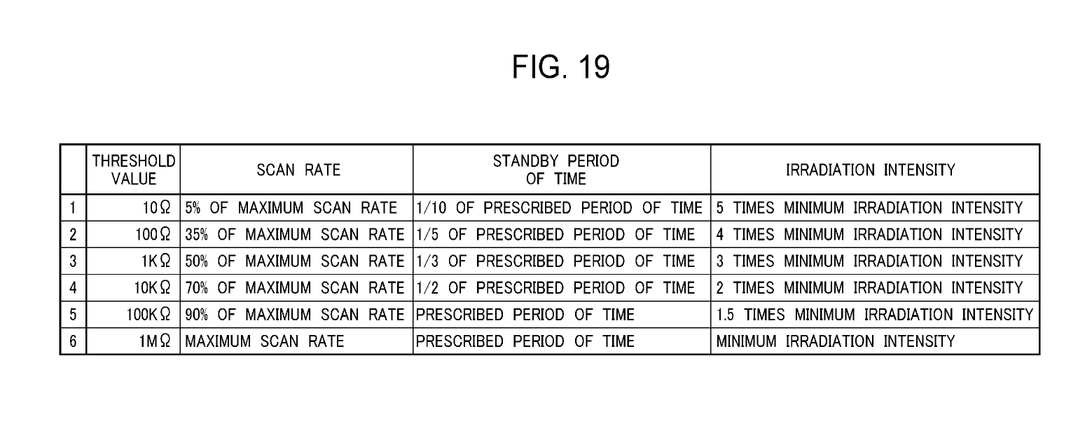

Then, the control processing unit 10 sets the threshold value at the initial value (Step S45). The initial value of the threshold value, i.e., the threshold value of the first stage is, e.g., 10Ω (see FIG. 19). The control processing unit 10 stores the set threshold value in, e.g., the threshold memory (not illustrated) provided in the memory unit 14. The control processing unit 10 sets the scan rate of the ion beam 35 at the initial value (Step S45). For example, the initial value of the scan rate of the ion beam 35 is, e.g., 5% of the maximum scan rate of the energy beam processing apparatus according to the present embodiment (see FIG. 19). The control processing unit 10 also sets the value of the standby period of time from the completion of one scan to the start of the next scan at the initial value (Step S45). The initial value of the standby period of time is, e.g., 1/10 of the prescribed period of time described above. The control processing unit 10 also sets the irradiation intensity of the ion beam 35 at the initial value (Step S45). The initial value of the irradiation intensity of the ion beam 35 is, e.g., five times the minimum irradiation intensity of the energy beam processing apparatus according to the present embodiment (see FIG. 19).

In the same way as in Step S6 of the energy beam processing method according to the first embodiment described above with reference to FIG. 3, the control processing unit 10 commands the irradiation unit 36 to irradiate the ion beam 35 to the region-to-be-irradiated 44 (Step S46).

After the irradiation of the ion beam 35 by the irradiation unit 36 has been started, i.e., after Step S46, the control processing unit 10 makes the following processing.

That is, in the same way as in Step S7 of the energy beam processing method according to the first embodiment described above with reference to FIG. 3, the control processing unit 10 compares the resistance value of the interconnection 42c measured by the measurement unit 32 with the preset threshold value (Step S47).

FIG. 19 is the table of the threshold values, the scan rates, the standby periods of time and the irradiation intensities of the respective stages.

As illustrated in FIG. 19, the threshold values of the respective stages are the same as the threshold values of the respective stages of the energy beam processing method according to the first and the second embodiments described above with reference to FIGS. 6 and 14. As illustrated in FIG. 19, the scan rates and the standby periods of time of the respective stages are the same as the scan rates and the standby periods of time of the respective stages of the energy beam processing method according to the first embodiment described above with reference to FIG. 6. As illustrated in FIG. 19, the irradiation intensities of the respective stages are the same as the irradiation intensities of the respective stages of the energy beam processing method according to the second embodiment described above with reference to FIG. 14.

The table illustrated in FIG. 19 is stored in, e.g., the memory unit 14.

When the resistance value of the interconnection 42c is smaller than the preset threshold value (Step S48), the processing is returned to Step S47.

On the other hand, when the resistance value of the interconnection 42c is equal to or larger than the preset threshold value (Step S48), the control processing unit 10 confirms whether or not the threshold value concerned is the threshold value of the final stage (Step S40).

When the threshold value concerned is not the threshold value of the final stage, the control processing unit 10 renews the threshold value, the scan rage, the standby period of time and the irradiation intensity as follows, based on the measured resistance value of the interconnection 42c (Step S50).

When the measured resistance value of the interconnection 42c is larger than the threshold value of the first stage, and equal to or smaller than the threshold value of the second stage, the control processing unit 10 sets the threshold value at the threshold value of the second stage. In this case, the control processing unit 10 sets the scan rate at the scan rate of the second stage. In this case, the control processing unit 10 sets the standby period of time at the standby period of time of the second stage. In this case, the control processing unit 10 sets the irradiation intensity of the energy beam 35 at the irradiation intensity of the second stage.

When the measured resistance value of the interconnection 42c is larger than the threshold value of the second stage and equal to or smaller than the threshold value of the third stage, the control processing unit 10 sets the threshold value at the threshold value of the third stage. In this case, the control processing unit 10 sets the scan rate at the scan rate of the third stage. In this case, the control processing unit 10 sets the standby period of time at the standby period of time of the third stage. The control processing unit 10 sets the irradiation intensity of the energy beam 35 at the irradiation intensity of the third stage.

When the measured resistance value of the interconnection 42c is larger than the threshold value of the third stage, and equal to or smaller than the threshold value of the fourth stage, the control processing unit 10 sets the threshold value at the threshold value of the fourth stage. In this case, the control processing unit 10 sets the scan rate at the scan rate of the fourth stage. In this case, the control processing unit 10 sets the standby period of time at the standby period of time of the fourth stage. In this case, the control processing unit 10 sets the irradiation intensity of the energy beam 35 at the irradiation intensity of the fourth stage.

When the measured resistance value of the interconnection 42c is larger than the threshold value of the fourth stage, and equal to or smaller than the threshold value of the fifth stage, the control processing unit 10 sets the threshold value at the threshold value of the fifth stage. In this case, the control processing unit 10 sets the scan rate at the scan rate of the fifth stage. In this case, the control processing unit 10 sets the standby period of time at the standby period of time of the fifth stage. In this case, the control processing unit 10 sets the irradiation intensity of the energy beam 35 at the irradiation intensity of the fifth stage.

When the measured resistance value of the interconnection 42c is larger than the threshold value of the fifth stage, and equal to or smaller than the threshold value of the sixth stage, the control processing unit 10 sets the threshold value at the threshold value of the sixth stage, i.e., the threshold value of the final stage. In this case, the control processing unit 10 sets the scan rate at the scan rate of the sixth stage. In this case, the control processing unit 10 sets the standby period of time at the standby period of time of the sixth stage. In this case, the control processing unit 10 sets the irradiation intensity of the energy beam 35 at the irradiation intensity of the sixth stage.

The control processing unit 10 stores the thus decided threshold values, e.g., in the threshold memory (not illustrated) provided in the memory unit 14. The control processing unit 10 outputs the information of decided scan rate, standby period of time and irradiation intensity to the irradiation unit 36. When the scan rage, the standby period of time and the irradiation intensity are renewed by the control processing unit 10, the irradiation unit 36 scans the energy beam 35 at the renewed scan rage, standby period of time and irradiation intensity.

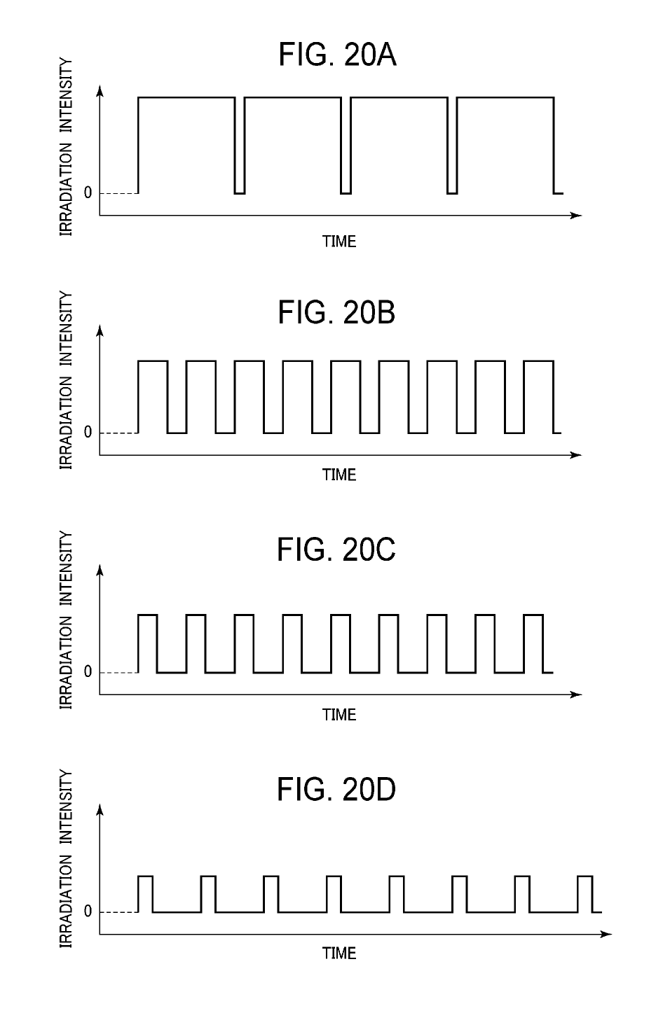

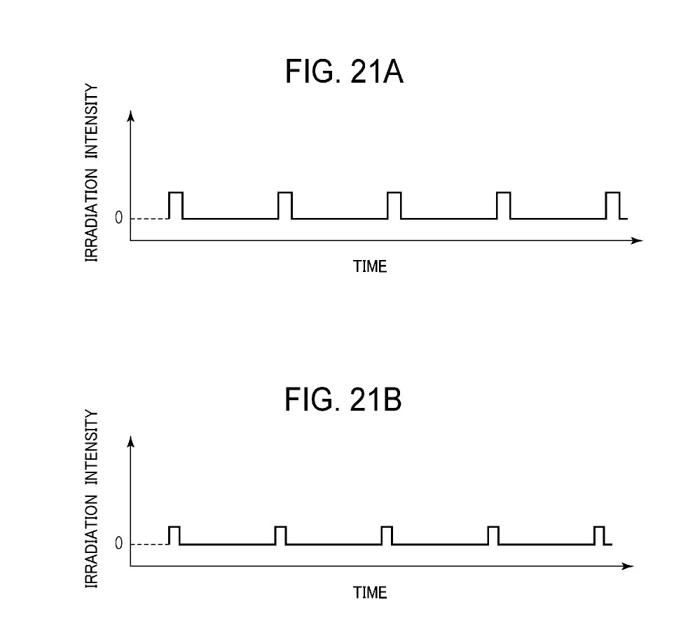

FIGS. 20A to 21B are the time charts of the irradiation of the ion beam. On the horizontal axis of FIGS. 20A to 21B, time is taken, and the irradiation intensity of the ion beam is taken on the vertical axis of FIGS. 20A to 21B. FIG. 20A illustrates the time chart of the first stage. FIG. 20B illustrates the time chart of the second stage. FIG. 20C illustrates the time chart of the third stage. FIG. 20D illustrates the time chart of the fourth stage. FIG. 21A illustrates the time chart of the fifth stage. FIG. 21B illustrates the time chart of the sixth stage.

In the present embodiment, as in the first embodiment, the scan rate is higher as the measured resistance value of the interconnection 42c becomes larger (see FIG. 9).

In the present embodiment, as in the first embodiment, the standby period of time is longer as the measured resistance value of the interconnection 42c becomes larger (see FIG. 10).

In the present embodiment as in the second embodiment, the irradiation intensity is lower as the measured resistance value of the interconnection 42c becomes larger (see FIG. 17).

After the threshold value, the scan rate, the standby period of time and the irradiation intensity have been renewed, i.e., after Step S50, the control processing unit 10 repeats the processing of Step S47 and the following steps.

When the measured resistance value of the interconnection 42c exceeds the threshold value of the sixth stage, i.e., the threshold value of the final stage (Step S49), the control processing unit 10 judges that the interconnection 42c has been cut off. In this case, the control processing unit 10 controls the irradiation unit 36 to stop the irradiation of the ion beam 35 (Step S51). Thus, the irradiation of the ion beam 35 to the region-to-be-irradiated 44 is finished.

Next, the measurement of the resistance value of the interconnection 42c by the measurement unit 32 is finished (Step S52).

Next, the probes 22a, 22b and the interconnection 42c are disconnected (Step S53).

Thus, the energy beam processing method according to the present embodiment is completed.

As described above, according to the present embodiment, the scan rate, the standby period of time and irradiation intensity of the ion beam 35 are set in accordance with the resistance value of the interconnection 42c. At the stage where the resistance value of the interconnection 42c is small, the scan rate is low, which can accelerate the cut-off of the interconnection 42c. At the stage where the resistance value of the interconnection 42c is low, the standby period of time is short, which can improve the throughput. On the other hand, at the stage where the resistance value of the interconnection 42c becomes larger, the scan rage is high, which can suppress damaging the lower layer interconnections, etc. At the stage where the resistance value of the interconnection 42c becomes larger, the standby period of time is longer, which, even when the interconnection 42c has been cut off by one scan, can prevent the start of the next scan, and consequently, damaging the lower interconnections, etc. can be prevented. At the stage where the resistance value of the interconnection 42c is small, the irradiation intensity of the ion beam 35 is high, which can accelerate the cut-off the interconnection 42c. On the other hand, at the stage where the resistance value of the interconnection 42c becomes larger, because of the low irradiation intensity, damaging the lower layer interconnections, erroneous cut-off of the lower layer interconnections, etc. can be suppressed. According to the present embodiment, the interconnection 42c can be cut off with high throughputs while impairing the reliability is further suppressed.

### A First Modification

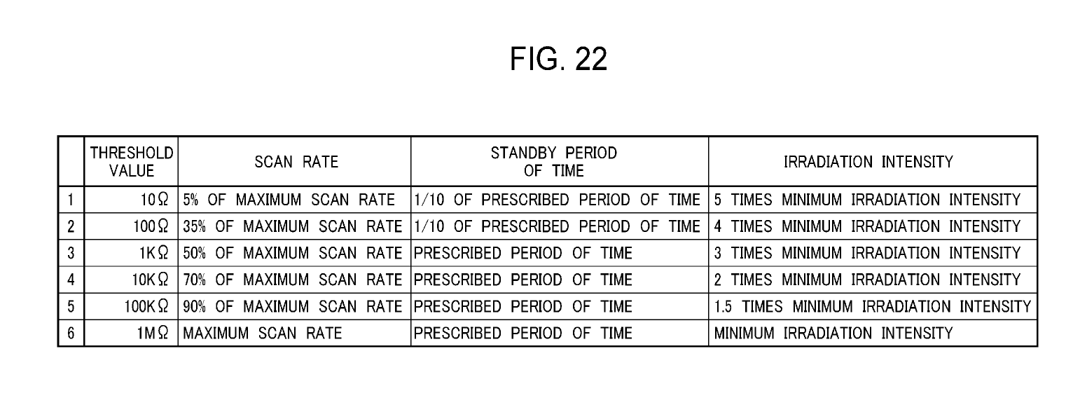

Next, the energy beam processing apparatus and processing method according to a first modification of the present embodiment will be described with reference to FIG. 22. FIG. 22 is the table of the threshold values, the scan rates and the standby period of time of the respective stages of the present modification.

As illustrated in FIG. 22, in the present modification, the threshold values of the respective stages are set same as in the third embodiment described above with reference to FIG. 19. The scan rates of the respective stages are also set same as in the third embodiment described above with reference to FIG. 19. The irradiation intensities of the respective stages are also set same as in the third embodiment described above with reference to FIG. 19.

However, in the present embodiment, the standby period of time has two kinds. That is, for the irradiation of the first stage and the second stage, the standby period of time is, e.g., 1/10 of the prescribed period of time described above. For the irradiation of the third stage to the sixth stage, the standby period of time is the prescribed period of time described above.

The table of FIG. 22 is stored in, e.g., the memory unit 14.

The combination of the threshold values, the scan rates and the standby periods of time of the respective stages may be set as in the present modification.

### A Second Modification

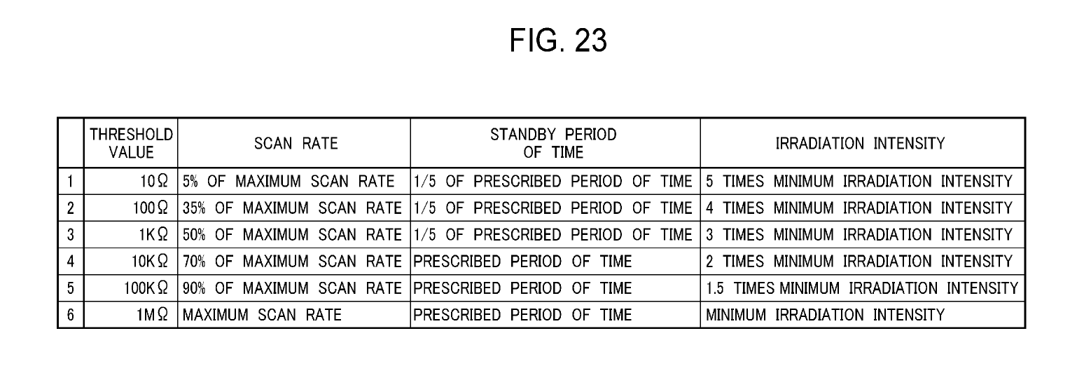

Then, the energy beam processing apparatus and processing method according to a second modification of the present embodiment will be described with reference to FIG. 23. FIG. 23 is the table of the threshold values, the scan rates and standby periods of time of the respective stage of the present modification.

As illustrated in FIG. 23, in the present modification, the threshold values of the respective stages are set same as in the third embodiment described above with reference to FIG. 19. The scan rates of the respective stages are also set same as in the third embodiment described above with reference to FIG. 19. The irradiation intensities of the respective stages are set same as in the third embodiment described above with reference to FIG. 19.

However, in the present modification, the standby period of time has two kinds. That is, the standby period of time for the irradiation of the first stage to the third stage is, e.g., ⅕ of the prescribed period of time described above. For the irradiation of the fourth stage to the sixth stage, the standby period of time is the prescribed period of time described above.

The table of FIG. 23 is stored in, e.g., the memory unit 14.

The threshold values, the scan rates and the standby period of time of the respective stages may be combined as in the present modification.

### Modified Embodiments

The present invention is not limited to the above-described embodiments and can cover other various modifications.

For example, the above-described embodiments are described by means of examples that the energy beam to be irradiated to the interconnection 42c to be cut off is an ion beam. The energy beam is not limited to an ion beam. For example, a laser beam, an electron beam, etc. may be used.

The second embodiment is described by means of the example that the irradiation intensity alone of the ion beam 35 is changed, based on the measured resistance value of the interconnection 42c. Not only the irradiation intensity of the ion beam 35 but also the scan rate thereof may be changed. In this case, the scan rates of the respective stages are set as in, e.g., the first embodiment.

The second embodiment is described by means of the example that the irradiation intensity alone of the ion beam 35 is changed, based on the measured resistance value of the interconnection 42c. Not only the irradiation intensity of the ion beam 35 but also the standby period of time may be changed. In this case, the standby periods of time of the respective stages are set as in, e.g., the first embodiment.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. An energy beam processing apparatus cutting an interconnection by irradiating the interconnection with an energy beam while scanning, the energy beam processing apparatus comprising:
an irradiation unit which irradiates the interconnection with the energy beam while scanning;
a measurement unit which measures a resistance value of the interconnection; and
a control unit which controls a scan and an irradiation of the energy beam by the irradiation unit, the control unit controlling at least one of a scan rate and an irradiation intensity of the energy beam in accordance with a resistance value measured by the measurement unit, and controlling the irradiation unit to stop the irradiation of the energy beam when the resistance value measured by the measurement unit exceeds a prescribed value.

2. The energy beam processing apparatus according to claim 1, wherein
the control unit controls the irradiation unit to increase the scan rate of the energy beam as the resistance value measured by the measurement unit becomes larger.

3. The energy beam processing apparatus according to claim 1, wherein
the control unit controls the irradiation unit to decrease the irradiation intensity of the energy beam as the resistance value measured by the measurement unit becomes larger.

4. The energy beam processing apparatus according to claim 1, wherein
the irradiation unit sequentially scans a plurality of partial regions of the interconnection, and
the control unit sets a standby period of time from a completion of a scan over one partial region of the plurality of partial regions to a start of a scan over another partial region of the plurality of partial regions adjacent to the one partial region in accordance with the resistance value measured by the measurement unit.

5. The energy beam processing apparatus according to claim 4, wherein
the control unit increases the standby period of time as the resistance value measured by the measurement unit becomes larger.

6. The energy beam processing apparatus according to claim 1, wherein
the energy beam is an ion beam.

7. An energy beam processing method cutting an interconnection by irradiating the interconnection with the energy beam while scanning, the energy beam processing method comprising:
irradiating the interconnection with the energy beam while scanning while controlling at least one of a scan rate and an irradiation intensity of the energy beam in accordance with a resistance value of the interconnection; and
stopping the irradiation of the energy beam when the resistance value of the interconnection exceeds a prescribed value.

8. The energy beam processing method according to claim 7, wherein
in the irradiating the interconnection with the energy beam while scanning, the scan rate of the energy beam is increased as the resistance value of the interconnection becomes larger.

9. The energy beam processing method according to claim 7, wherein
in the irradiating the interconnection with the energy beam while scanning, the irradiation intensity of the energy beam is decreased as the resistance value of the interconnection becomes larger.

10. The energy beam processing method according to claim 7, wherein
in the irradiating the interconnection with the energy beam while scanning, a plurality of partial regions of the interconnection are sequentially scanned, and a standby period of time from a completion of a scan over one partial region of the plurality of partial regions to a start of a scan over another partial region of the plurality of partial regions adjacent to the one partial region is set in accordance with a resistance value of the interconnection.

11. The energy beam processing method according to claim 10, wherein
in the irradiating the interconnection with the energy beam while scanning, the standby period of time is increased as the resistance value of the interconnection becomes larger.
